(19) United States
(12) Patent Application Publication
(10) Pub. No.: US 2025/0298092 A1
(43) Pub. Date: Sep. 25, 2025

(54) Inspection Tool

(71) Applicants: Tyco Electronics (Zhuhai) Ltd., Zhuhai (CN); TE Connectivity Solutions GmbH, Schaffhausen (CH); Tyco Electronics (Shanghai) Co., Ltd., Shanghai (CN)

(72) Inventors: Lei (Alex) Zhou, Shanghai (CN); Wei Zheng, Zhuhai (CN); Dandan (Emily) Zhang, Shanghai (CN); Roberto Francisco-Yi Lu, Bellevue, WA (US); Tengjin Su, Zhuhai (CN); Liang Wen, Zhuhai (CN); Ming (Micky) Jiang, Zhuhai (CN); Liqing (Mary) Ma, Zhuhai (CN)

(73) Assignees: Tyco Electronics (Zhuhai) Ltd., Zhuhai (CN); TE Connectivity Solutions GmbH, Schaffhausen (CH); Tyco Electronics (Shanghai) Co., Ltd., Shanghai (CN)

(21) Appl. No.: 19/089,557

(22) Filed: Mar. 25, 2025

(30) Foreign Application Priority Data
Mar. 25, 2024 (CN) 202410350007.X

(51) Int. Cl. G01R 31/66

(52) U.S. Cl. CPC G01R 31/66

(57) ABSTRACT

An inspection tool includes a plurality of different measurement blocks assembled together. The different measurement blocks include a first measurement block having a plurality of first insertion holes; a layout and a position of the first insertion holes are consistent with a plurality of first pins of a first shell unit of a standard shell. The first pins on the first shell unit of the standard shell are insertable into the first insertion holes in the first measurement block. The first measurement block is used to check whether a layout and a position of a plurality of first pins on an inspected shell are qualified.

### CROSS-REFERENCE TO RELATED APPLICATION

This application claims the benefit of the filing date under 35 U.S.C. § 119 (a)-(d) of Chinese Patent Application No. CN202410350007.X, filed on Mar. 25, 2024.

### FIELD OF THE INVENTION

The present invention relates to an inspection tool, particularly to an inspection tool for checking whether the layout and position of pins on a shell of a connector are qualified.

### BACKGROUND OF THE INVENTION

Multiple pins are formed at the bottom of the connector shell for respectively plugging into multiple insertion holes in the circuit board. The pins at the bottom of the shell are arranged in a predetermined layout and position distribution. During the manufacturing process of the connector shell, it is necessary to conduct quality inspection on the layout and position of multiple pins at the bottom of the shell. Measuring tools are usually used for inspection, which have multiple insertion holes formed in the measuring tool. The number, layout, position, and orientation of the multiple insertion holes correspond to the multiple pins on a standard shell (i.e. the ideal shell with fully qualified quality). When multiple pins on the inspected shell can be inserted into multiple insertion holes in the measuring tool, it indicates that the layout and position of the multiple pins on the inspected shell are qualified. Otherwise, it indicates that the layout and position of the multiple pins on the inspected shell are unqualified. However, the number, layout, position, or orientation of pins on different types of shells are different, which requires providing a corresponding inspection tool for each type of shell, resulting in higher costs.

### SUMMARY OF THE INVENTION

An inspection tool includes a plurality of different measurement blocks assembled together. The different measurement blocks include a first measurement block having a plurality of first insertion holes; a layout and a position of the first insertion holes are consistent with a plurality of first pins of a first shell unit of a standard shell. The first pins on the first shell unit of the standard shell are insertable into the first insertion holes in the first measurement block. The first measurement block is used to check whether a layout and a position of a plurality of first pins on an inspected shell are qualified.

### BRIEF DESCRIPTION OF THE DRAWINGS

The invention will now be described by way of example with reference to the accompanying figures, of which:

FIG. 1 shows an illustrative perspective view of an inspection tool according to an exemplary embodiment of the present invention;

FIG. 2 shows an illustrative exploded view of an inspection tool according to an exemplary embodiment of the present invention;

FIG. 3 shows an illustrative assembly view of multiple measurement blocks and multiple partition plates of an inspection tool according to an exemplary embodiment of the present invention;

FIG. 4 shows an illustrative exploded view of multiple measurement blocks and multiple partition plates of an inspection tool according to an exemplary embodiment of the present invention; and

FIG. 5 shows an illustrative assembly view of multiple measurement blocks and multiple partition plates of an inspection tool according to another exemplary embodiment of the present invention.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

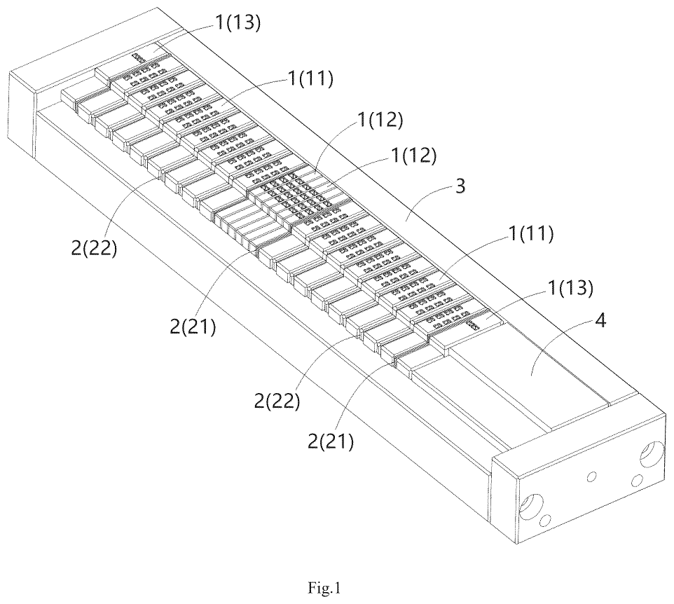

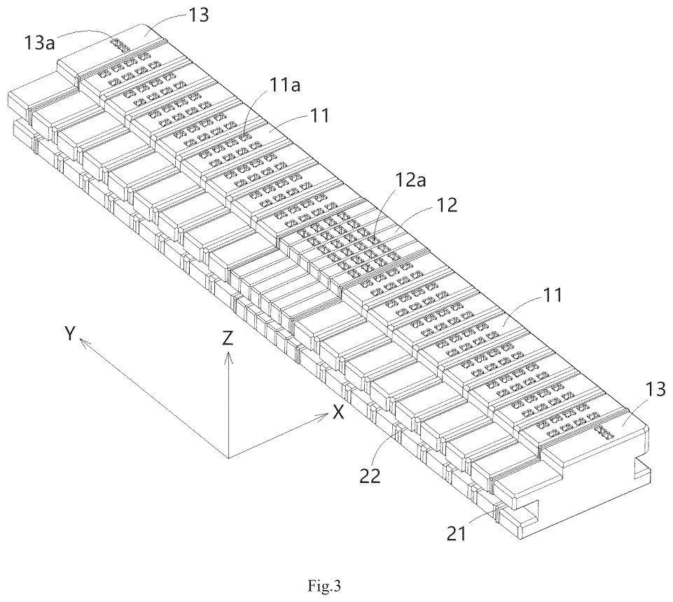

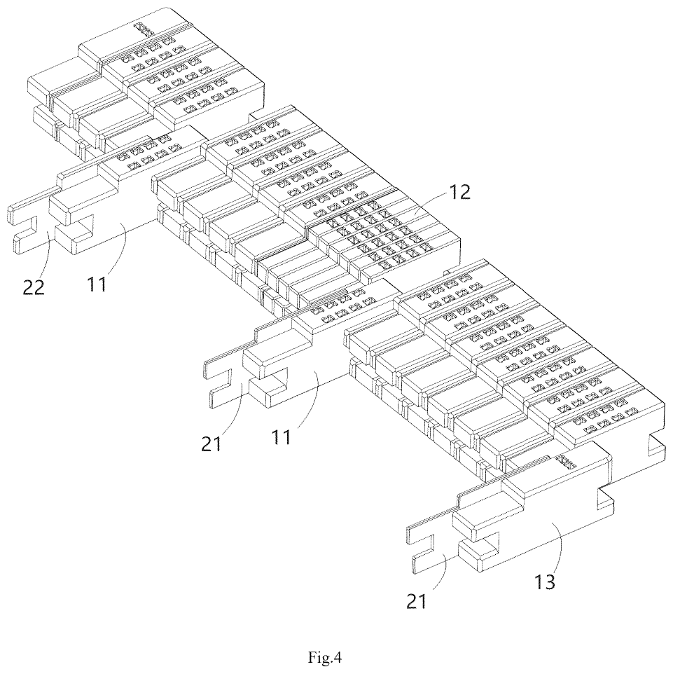

As shown in FIGS. 1 to 4, in an exemplary embodiment of the present invention, an inspection tool is disclosed. The inspection tool includes a plurality of different measurement blocks 1 assembled together. The different measurement blocks 1 include a first measurement block 11. Multiple first insertion holes 11a are formed in the first measurement block 11, as shown in FIG. 3, and the layout and position of the multiple first insertion holes 11a are consistent with multiple first pins of a first shell unit of a standard shell (i.e., an ideal shell with fully qualified quality), so that the multiple first pins on the first shell unit of the standard shell can be inserted into the multiple first insertion holes 11a in the first measurement block 11. The first measurement block 11 is used to check whether the layout and position of multiple first pins on the first shell unit of the inspected shell are qualified.

When the layout and position of the multiple first pins on the first shell unit of the inspected shell are qualified, the multiple first pins on the first shell unit of the inspected shell can be inserted into the multiple first insertion holes 11a in the first measurement block 11. When the layout and/or position of multiple first pins on the first shell unit of the inspected shell is not qualified, the multiple first pins on the first shell unit of the inspected shell cannot be inserted into the multiple first insertion holes 11a in the first measurement block 11.

As shown in FIGS. 1 to 4, in the illustrated embodiment, the inspection tool includes multiple first measurement blocks 11, which are assembled to correspond to multiple first shell units of the standard shell, and are used to simultaneously inspect whether the layout and position of the first pins on the multiple first shell units of the inspected shell are qualified.

When the layout and position of the first pins on multiple first shell units of the inspected shell are qualified, the first pins on multiple first shell units of the inspected shell can be inserted into the first insertion holes 11a in multiple first measurement blocks 11. When the layout and/or position of the first pins on multiple first shell units of the inspected shell are not qualified, the first pins on multiple first shell units of the inspected shell cannot be inserted into the first insertion holes 11a in multiple first measurement blocks 11.

As shown in FIGS. 1 to 4, in the illustrated embodiment, the number and/or position of the first measurement blocks 11 in the inspection tool can be adjusted according to different types of standard shells, so that the inspection tool can be used to inspect the layout and position of the first pins of the first shell units of different types of inspected shells.

As shown in FIG. 3, in the illustrated embodiment, the first measurement block 11 includes left and right sides opposite in the first direction Y, front and rear sides opposite in the second direction X, and upper and lower sides opposite in the third direction Z. The first insertion hole 11a penetrates through the first measurement block 11 along the third direction Z, as shown in FIG. 3, and multiple first measurement blocks 11 are assembled in the first direction Y to correspond to multiple first shell units of the standard shell.

As shown in FIG. 3, in the illustrated embodiment, multiple first insertion holes 11a in the first measurement block 11 are arranged in multiple rows and columns, with the first direction Y being the row direction and the second direction X being the column direction. In the illustrated embodiment, eight first insertion holes 11a are formed in the first measurement block 11, and the eight first insertion holes 11a are arranged in four rows and two columns.

As shown in FIGS. 1 to 4, in the illustrated embodiment, the multiple different measurement blocks 1 further include a second measurement block 12, on which multiple second insertion holes 12a are formed. The layout and position of the multiple second insertion holes 12a are consistent with the multiple second pins of a second shell unit of the standard shell, so that the multiple second pins on the second shell unit of the standard shell can be inserted into the multiple second insertion holes 12a in the second measurement block 12. The number, layout, position, or orientation of multiple second insertion holes 12a in the second measurement block 12 is different from that of the multiple first insertion holes 11a in the first measurement block 11. The second measurement block 12 is used to check whether the layout and position of multiple second pins on the second shell unit of the inspected shell are qualified.

When the layout and position of the multiple second pins on the second shell unit of the inspected shell are qualified, the multiple second pins on the second shell unit of the inspected shell can be inserted into the multiple second insertion holes 12a in the second measurement block 12. When the layout and/or position of multiple second pins on the second shell unit of the inspected shell is not qualified, the multiple second pins on the second shell unit of the inspected shell cannot be inserted into the multiple second insertion holes 12a in the second measurement block 12. In the illustrated embodiment, the inspection tool includes multiple second measurement blocks 12, which are assembled to correspond to multiple second shell units of the standard shell, and are used to simultaneously check whether the layout and position of the second pins on the multiple second shell units of the inspected shell are qualified.

When the layout and position of the second pins on multiple second shell units of the inspected shell are qualified, the second pins on multiple second shell units of the inspected shell can be inserted into the second insertion holes 12a in multiple second measurement blocks 12. When the layout and/or position of the second pins on multiple second shell units of the inspected shell are not qualified, the second pins on multiple second shell units of the inspected shell cannot be inserted into the second insertion holes 12a in multiple second measurement blocks 12.

In the illustrated embodiment, the number and/or position of the second measurement blocks 12 in the inspection tool can be adjusted according to different types of standard shells, so that the inspection tool can be used to inspect the layout and position of the second pins of the second shell units of different types of inspected shells.

As shown in FIG. 3, in the illustrated embodiment, the second measurement block 12 includes left and right sides opposite in the first direction Y, front and rear sides opposite in the second direction X, and upper and lower sides opposite in the third direction Z. The second insertion hole 12a penetrates through the second measurement block 12 along the third direction Z, and multiple second measurement blocks 12 are assembled in the first direction Y to correspond to multiple second shell units of the standard shell.

As shown in FIG. 3, in the illustrated embodiment, multiple second insertion holes 12a in the second measurement block 12 are arranged in a row in the second direction X. In the illustrated embodiment, four second insertion holes 12a are formed in the second measurement block 12, and the four second insertion holes 12a are arranged in a row in the second direction X.

As shown in FIGS. 1 to 4, in the illustrated embodiment, multiple different measurement blocks 1 also include a third measurement block 13, on which multiple third insertion holes 13a are formed, and the layout and position of the multiple third insertion holes 13a are consistent with the multiple third pins of a third shell unit of the standard shell, so that the multiple third pins on the third shell unit of the standard shell can be inserted into the multiple third insertion holes 13a in the third measurement block 13. The number, layout, position or orientation of multiple third insertion holes 13a in the third measurement block 13 is different from that of the multiple first insertion holes 11a in the first measurement block 11 and also different from that of the multiple second insertion holes 12a in the second measurement block 12. The third measurement block 13 is used to check whether the layout and position of multiple third pins on the third shell unit of the inspected shell are qualified.

When the layout and position of the multiple third pins on the third shell unit of the inspected shell are qualified, the multiple third pins on the third shell unit of the inspected shell can be inserted into the multiple third insertion holes 13a in the third measurement block 13. When the layout and/or position of multiple third pins on the third shell unit of the inspected shell is not qualified, the multiple third pins on the third shell unit of the inspected shell cannot be inserted into the multiple third insertion holes 13a in the third measurement block 13.

In the illustrated embodiment, the inspection tool includes multiple third measurement blocks 13, which are assembled to correspond to multiple third shell units of the standard shell, and are used to simultaneously check whether the layout and position of the third pins on the multiple third shell units of the inspected shell are qualified.

When the layout and position of the third pins on multiple third shell units of the inspected shell are qualified, the third pins on multiple third shell units of the inspected shell can be inserted into the third insertion holes 13a in multiple third measurement blocks 13. When the layout and/or position of the third pins on multiple third shell units of the inspected shell are not qualified, the third pins on multiple third shell units of the inspected shell cannot be inserted into the third insertion holes 13a in multiple third measurement blocks 13.

In the illustrated embodiment, the number and/or position of the third measurement blocks 13 in the inspection tool can be adjusted according to different types of standard shells, so that the inspection tool can be used to inspect the layout and position of the third pins of the third shell units of different types of inspected shells.

As shown in FIG. 3, in the illustrated embodiment, the third measurement block 13 includes left and right sides opposite in the first direction Y, front and rear sides opposite in the second direction X, and upper and lower sides opposite in the third direction Z. The third insertion hole 13a penetrates through the third measurement block 13 along the third direction Z, and multiple third measurement blocks 13 are assembled in the first direction Y to correspond to multiple third shell units of the standard shell.

As shown in FIG. 3, in the illustrated embodiment, multiple third insertion holes 13a in the third measurement block 13 are arranged in a row in the first direction Y. In the illustrated embodiment, two third insertion holes 13a are formed in the third measurement block 13, and the two third insertion holes 13a are arranged in a row in the first direction Y.

As shown in FIG. 1, in the illustrated embodiment, the inspection tool further includes multiple partition plates 2, each of which is clamped between adjacent measurement blocks 1 to adjust the spacing between them. In the illustrated embodiment, the multiple partition plates 2 include a first partition plate 21 and a second partition plate 22. The first partition plate 21 has a first thickness. The second partition plate 22 has a second thickness, with the first thickness being different from the second thickness. In the illustrated embodiment, the second thickness is equal to one and a half times, two times, two and a half times, three times, or three and a half times the first thickness. However, the present invention is not limited to the illustrated embodiments, and the ratio between the second thickness and the first thickness may also be other values.

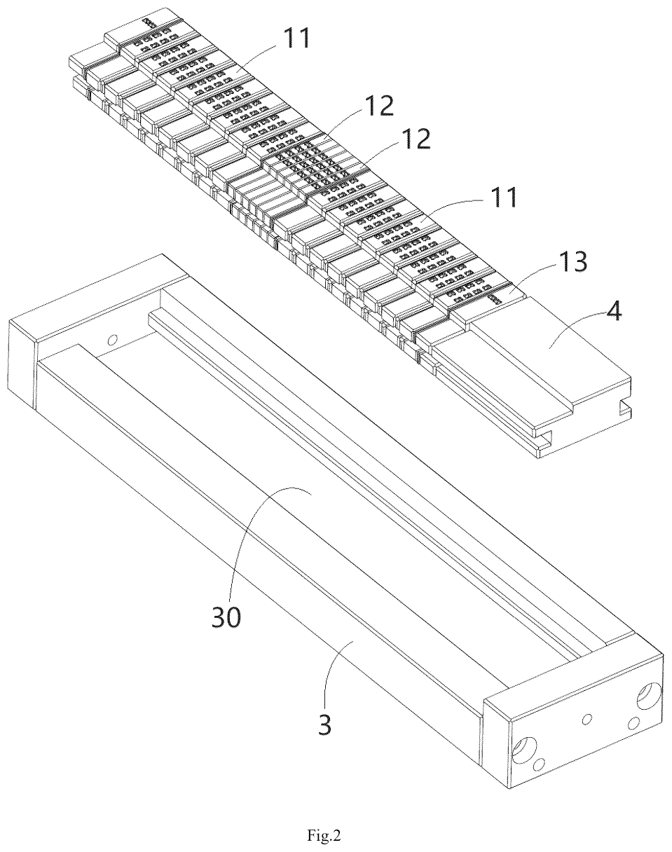

As shown in FIGS. 1 and 2, in the illustrated embodiment, the inspection tool further comprises a frame body 3, in which an installation chamber 30 is formed. Multiple measurement blocks 1 and multiple partition plates 2 are assembled in the installation chamber 30 of the frame body 3, and the front and rear sides of the measurement blocks 1 and partition plates 2 are respectively pressed against the front and rear inner walls of the installation chamber 30.

The inspection tool further includes a positioning block 4, shown in FIGS. 1 and 2, which is set in the installation chamber 30 of the frame body 3. Multiple measurement blocks 1 are arranged in a row, and the rightmost measurement block 1 of the multiple measurement blocks 1 is pressed against the inner surface of the right side of the installation chamber 30. The left side of positioning block 4 is pressed against the inner surface of the left side of installation chamber 30, and the right side of positioning block 4 is pressed against the side of the leftmost measurement block 1 among multiple measurement blocks 1.

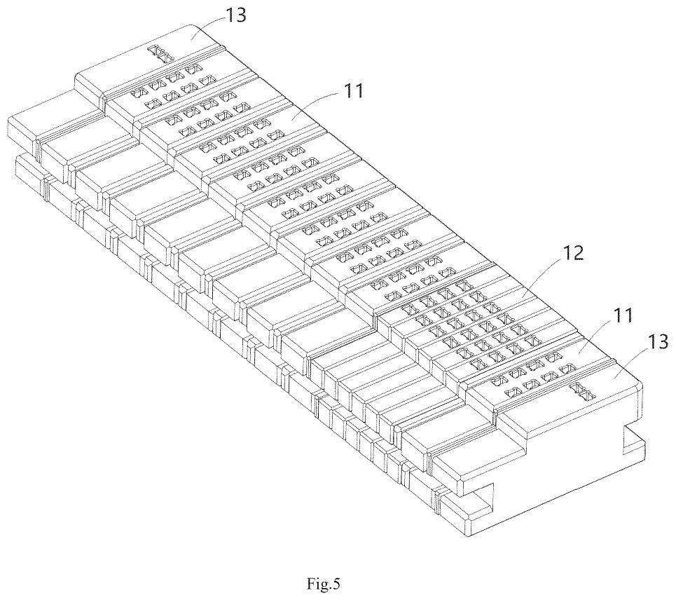

FIG. 5 shows an illustrative assembly view of multiple measurement blocks 1 and multiple partition plates 2 of an inspection tool according to another exemplary embodiment of the present invention. The difference between the inspection tool shown in FIG. 5 and the inspection tool shown in FIGS. 1-4 is the number of first measurement blocks 11. Therefore, the type of the inspection tool shown in FIG. 5 is different from the inspection tool shown in FIGS. 1-4. That is to say, multiple measurement blocks 1 can be assembled into various types of inspection tools, eliminating the need to manufacture different types of inspection tools separately and reducing costs.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. An inspection tool, comprising:
a plurality of different measurement blocks assembled together, the different measurement blocks include a first measurement block having a plurality of first insertion holes, a layout and a position of the first insertion holes are consistent with a plurality of first pins of a first shell unit of a standard shell, the first pins on the first shell unit of the standard shell are insertable into the first insertion holes in the first measurement block, the first measurement block is used to check whether a layout and a position of a plurality of first pins on a first shell unit of an inspected shell are qualified.

2. The inspection tool according to claim 1, wherein, when the layout and the position of the first pins on the first shell unit of the inspected shell are qualified, the first pins of the inspected shell are insertable into the first insertion holes in the first measurement block, and when the layout and/or the position of the first pins on the first shell unit of the inspected shell is not qualified, the first pins of the inspected shell cannot be inserted into the first insertion holes in the first measurement block.

3. The inspection tool according to claim 2, wherein the first measurement block is one of a plurality of first measurement blocks of the different measurement blocks, the first measurement blocks are assembled to correspond to a plurality of first shell units of the standard shell, and are used to simultaneously inspect whether the layout and the position of the first pins on a plurality of first shell units of the inspected shell are qualified.

4. The inspection tool according to claim 3, wherein the number and/or the position of the first measurement blocks in the inspection tool is adjustable according to different types of standard shells, the inspection tool can be used to inspect the layout and the position of the first pins of the first shell units of different types of inspected shells.

5. The inspection tool according to claim 3, wherein the first measurement blocks each include a left side and a right side opposite in a first direction, a front side and a rear side opposite in a second direction, and an upper side and a lower side opposite in a third direction, the first insertion holes penetrate through the first measurement blocks along the third direction, and the first measurement blocks are assembled in the first direction to correspond to the first shell units of the standard shell.

6. The inspection tool according to claim 5, wherein the first insertion holes in each of the first measurement blocks are arranged in a plurality of rows and columns, the first direction is a row direction, and the second direction is a column direction.

7. The inspection tool according to claim 1, wherein the different measurement blocks include a second measurement block having a plurality of second insertion holes, a layout and a position of the second insertion holes are consistent with a plurality of second pins of a second shell unit of the standard shell, the second pins on the second shell unit of the standard shell are insertable into the second insertion holes in the second measurement block, a number, a layout, a position or an orientation of the second insertion holes in the second measurement block is different from that of the first insertion holes in the first measurement block, the second measurement block is used to check whether a layout and a position of a plurality of second pins on a second shell unit of an inspected shell are qualified.

8. The inspection tool according to claim 7, wherein, when the layout and the position of the second pins on the second shell unit of the inspected shell are qualified, the second pins on the second shell unit of the inspected shell are insertable into the second insertion holes in the second measurement block, and when the layout and/or the position of the second pins on the second shell unit of the inspected shell is not qualified, the second pins on the second shell unit of the inspected shell cannot be inserted into the second insertion holes in the second measurement block.

9. The inspection tool according to claim 7, wherein the second measurement block is one of a plurality of second measurement blocks assembled to correspond to a plurality of second shell units of the standard shell, the second measurement blocks simultaneously inspect whether the layout and the position of the second pins on the second shell units of the inspected shell are qualified.

10. The inspection tool according to claim 9, wherein the number and/or the position of the second measurement blocks in the inspection tool can be adjusted according to different types of standard shells, the inspection tool can be used to inspect the layout and the position of the second pins of the second shell units of different types of inspected shells.

11. The inspection tool according to claim 9, wherein the second measurement blocks each include a left side and a right side opposite in a first direction, a front side and a rear side opposite in a second direction, and an upper side and a lower side opposite in a third direction, the second insertion holes penetrate through the second measurement blocks along the third direction, the second measurement blocks are assembled in the first direction to correspond to the second shell units of the standard shell.

12. The inspection tool according to claim 11, wherein the second insertion holes in each of the second measurement blocks are arranged in a row in the second direction.

13. The inspection tool according to claim 7, wherein the different measurement blocks include a third measurement block having a plurality of third insertion holes, a layout and a position of the third insertion holes are consistent with a plurality of third pins of a third shell unit of the standard shell, the third pins on the third shell unit of the standard shell are insertable into the third insertion holes in the third measurement block, a number, a layout, a position or an orientation of third insertion holes in the third measurement block is different from that of the first insertion holes in the first measurement block and also different from that of the second insertion holes in the second measurement block, the third measurement block is used to check whether a layout and a position of a plurality of third pins on a third shell unit of the inspected shell are qualified.

14. The inspection tool according to claim 13, wherein, when the layout and the position of the third pins on the third shell unit of the inspected shell are qualified, the third pins on the third shell unit of the inspected shell are insertable into the third insertion holes in the third measurement block, and when the layout and/or the position of the third pins on the third shell unit of the inspected shell is not qualified, the third pins on the third shell unit of the inspected shell cannot be inserted into the third insertion holes in the third measurement block.

15. The inspection tool according to claim 13, wherein the third measurement block is one of a plurality of third measurement blocks assembled to correspond to a plurality of third shell units of the standard shell, the third measurement blocks simultaneously inspect whether the layout and the position of the third pins on the third shell units of the inspected shell are qualified.

16. The inspection tool according to claim 15, wherein the number and/or the position of the third measurement blocks in the inspection tool can be adjusted according to different types of standard shells, the inspection tool can be used to inspect the layout and the position of the third pins of the third shell unit of different types of inspected shells.

17. The inspection tool according to claim 15, wherein the third measurement blocks each include a left side and a right side opposite in a first direction, a front side and a rear side opposite in a second direction, and an upper side and a lower side opposite in a third direction, the third insertion holes penetrates through the third measurement blocks along the third direction, the third measurement blocks are assembled in the first direction to correspond to the third shell units of the standard shell.

18. The inspection tool according to claim 17, wherein the third insertion holes in the third measurement blocks are arranged in a row in the first direction.

19. The inspection tool according to claim 1, further comprising a plurality of partition plates, each partition plate is clamped between a pair of adjacent measurement blocks of the different measurement blocks to adjust a spacing between the pair of adjacent measurement blocks.

20. The inspection tool according to claim 19, wherein the partition plates include a first partition plate with a first thickness and a second partition plate with a second thickness, the first thickness is different from the second thickness.

21. The inspection tool according to claim 19, further comprising a frame body having an installation chamber, the different measurement blocks and the partition plates are assembled in the installation chamber of the frame body, and a front side and a rear side of the different measurement blocks and a front side and a rear side of the partition plates are respectively pressed against a front inner wall and a rear inner wall of the installation chamber.

22. The inspection tool according to claim 21, further comprising a positioning block disposed in the installation chamber of the frame body, the different measurement blocks are arranged in a row, and a rightmost measurement block of the different measurement blocks is pressed against an inner surface of a right side of the installation chamber, a left side of the positioning block is pressed against an inner surface of a left side of the installation chamber, a right side of the positioning block is pressed against a side of a leftmost measurement block of the different measurement blocks.
